(19) United States
(12) Patent Application Publication
(10) Pub. No.: US 2011/0128071 A1
(43) Pub. Date: Jun. 2, 2011

(54) FILTER AUTOMATIC ADJUSTMENT CIRCUIT AND METHOD FOR ADJUSTING CHARACTERISTIC FREQUENCY OF FILTER, AND WIRELESS COMMUNICATION APPARATUS PROVIDED WITH THE SAME

(76) Inventors: Masaru FUKUSEN, Shiga (JP); Daisuke Miyawaki, Hyogo (JP)

(21) Appl. No.: 12/880,433

(22) Filed: Sep. 13, 2010

(30) Foreign Application Priority Data
Nov. 27, 2009 (JP) 2009-269715

(51) Int. Cl. H03K 5/00

(52) U.S. Cl. 327/554; 327/553

(57) ABSTRACT

A filter automatic adjustment circuit is provided for adjusting a characteristic frequency of a main filter whose characteristic frequency is adjustable with a reference signal frequency served as a target frequency. A reference filter has modes selectively changed over, and filters an inputted reference signal. A phase difference detector detects a phase difference between an input signal inputted to the reference filter and an output signal from the reference filter, and outputs a signal having a duty ratio corresponding to a phase difference caused by the reference filter. A counter counts a duty ratio corresponding to the phase difference caused by the reference filter based on the output signal from the phase difference detector and the reference signal, and outputs a signal representing a counted duty ratio. A decoder decodes the output signal from the counter into a control signal for variation correction on the main filter.

### BACKGROUND OF THE INVENTION

1. Field of the Invention

The present invention relates to a filter automatic adjustment circuit and method for adjusting the characteristic frequency of a filter having an adjustment function to a target frequency and to a wireless communication apparatus such as a portable telephone system having a filter automatic adjustment circuit.

2. Description of the Related Art

In recent wireless communication apparatuses such as portable telephones, efforts are made to reduce the power consumption and size, and there is a trend of integrating a lot of wireless components. Filters have a similar trend and are often built-in. In general, regarding variations in the integrated circuit manufacturing processes, resistors have variations of plus or minus ten-odd percent, and capacitors have plus or minus ten-odd percent. The characteristic frequency of a filter as configured to include resistors and capacitors has a variation of not smaller than plus or minus twenty percent. It is an important problem to correct the variation in providing built-in filters. It is noted that the characteristic frequency means a center frequency f0 concerning a band-pass filter (BPF) and means a cutoff frequency (frequency at a point of −3 dB) concerning a high-pass filter (HPF) and a low-pass filter (LPF).

In a portable telephone with a built-in filter, the call duration of a portable telephone achievable by one-time battery charging is shortened if the power consumption of the filter is large. If the battery is enlarged to secure long call duration, size reduction of the portable telephone is not achieved. Under such a situation, a filter of lowest possible power consumption is necessary.

As the first prior art (See, for example, the Patent Document 1), there is a filter automatic adjustment method for adjusting a main filter by comparing the phase of the input signal of a reference filter with the phase of the output signal from the reference filter and feeding the phase comparison result back to the main filter.

FIG. 10 is a block diagram showing a configuration of the filter automatic adjustment circuit of the first prior art. Referring to FIG. 10, the filter automatic adjustment circuit is configured to include a reference signal generator 1, a reference filter 2, a phase difference detector 3, a control voltage generator 4, and a main filter 5. A signal having the characteristic frequency when the reference filter 2 has no variation is outputted from the reference signal generator 1. The output signal from the reference filter 2 and the input signal inputted to the reference filter 2 are inputted to the phase comparator 3. The output signal from the phase comparator 3 is inputted to the control voltage generator 4 that adjusts the filter by a phase difference, and the characteristic frequency of the main filter 5 is adjusted by receiving the output signal from the control voltage generator 4.

The reference filter 2 and the main filter 5 often have similar configurations to each other, and the reference filter 2 and the main filter 5 are configured to change the characteristic frequency in accordance with a control voltage outputted from the control voltage generator 4. If the control voltage is outputted from the control voltage generator 4 so as to adjust the characteristic frequency of the reference filter 2 by using the output signal from phase difference detector 3, the characteristic frequency of the main filter 5 is also adjusted. Moreover, the circuits 1 to 4 of FIG. 10 concerning the filter adjustment are consistently operating in the normal operating time, and the characteristic frequency of the main filter 5 is configured to be adjusted even when the characteristic frequency of the reference filter 2 and the main filter 5 shifts for the reasons of, for example, power voltage variation or the like.

As the second prior art (See, for example, the Patent Document 2), there is a method for turning off the power to supply power to a block relevant to the filter adjustment in the normal operating time by comparing the phase of the input signal of the reference filter with the phase of the output signal from the reference filter, digitally processing the comparison result and storing the resultant into an internal latch. The filter automatic adjustment circuit of the second prior art is described below with reference to FIGS. 11 to 14.

FIG. 11 is a block diagram showing a configuration of the filter automatic adjustment circuit of the second prior art. Referring to FIG. 11, the filter automatic adjustment circuit is configured to include a reference signal generator 11, a frequency divider 12, a reference filter 13, a phase difference detector 14, a comparator 15, a counter 16, a decoder 17, a register 18 and a main filter 19. In this case, the main filter 19 is configured to include a plurality of input resistors 21(1) to 21(n), a plurality of input resistors 22(1) to 22(n), switches 27 and 28, feedback capacitor 23, an input capacitor 24, and an operational amplifier 25.

Referring to FIG. 11, a reference signal outputted from the reference signal generator 11 is divided by the frequency divider 12. During the frequency division, the reference signal from the reference signal generator 11 is converted into the frequency of the characteristic frequency when the reference filter 13 has no variation. The output signal from the frequency divider 12 is inputted to the reference filter 13, and the input signal inputted to the reference filter 13 and the output signal from the reference filter 13 are inputted to the phase difference detector 14. The output signal from the phase difference detector 14 is converted into a square wave by the comparator 15. The output signal from the comparator 15 and the reference signal 11 are inputted to the counter 16, and the counter 16 counts the inputted signal.

FIG. 12 is a circuit diagram showing one example of the reference filter 13 of FIG. 11. Referring to FIG. 12, the reference filter 13 is configured to include input resistors 31 and 32, a feedback capacitor 33, an input capacitor 34, and an operational amplifier 35.

FIG. 13 is a timing chart for explaining the filter adjustment operation of the filter automatic adjustment circuit of FIG. 11, and FIG. 14 is a table showing relations between the CR product variation of the reference filter 13 in the filter adjustment operation of the filter automatic adjustment circuit of FIG. 11 and the count number. That is, FIG. 13 shows the state of the operation during counting. Referring to FIG. 13, if the counting is performed by the reference frequency for a high-level (hereinafter referred to as an H level) interval, when the output signal from the comparator 15 is present when there is no variation of the product (hereinafter referred to as a CR product) of the capacitance value of the capacitor and resistance value, then the count number is eight. Conversely, if the H-level intervals of the output signal from the comparator 15 are counted by the reference frequency when there is a CR product variation (when the CR product is −26%), then the count number is ten.

As shown in FIG. 14, the CR product variation can be found by counting for the interval when there is an output signal from the comparator 15. The count result is inputted to the decoder 17, and the decoded value (decoded result) is inputted to the register 18. The output signals 26(1) to 26(n) from the register 18 are inputted to the main filter 19, and one of the resistors 21(1) to 21(n) and one of the resistors 22(1) to 22(n) are selected by selective changeover of the switches 27 and 28 based on the output signals 26(1) to 26(n). The resistance values of these resistors 21(1) to 21(n) and the resistors 22(1) to 22(n) are designed based on resistance correction values shown in FIG. 14, and the apparent resistance variation can be suppressed.

Moreover, according to the filter automatic adjustment method of the second prior art, since the adjustment result is stored in the register 18, the power to the circuits 12 to 17 relevant to the automatic adjustment of the filter can be turned off if once adjusted, and this has a great advantage in terms of low power consumption.

Prior art documents related to the present invention are as follows:
Patent Document 1: Japanese patent laid-open publication No. JP 2002-76842 A; and
Patent Document 2: Japanese patent laid-open publication No. JP 2004-172911 A.

However, according to the filter automatic adjustment method of the first prior art as described above, the filter automatic adjustment circuit is always turned on, and a feedback loop is put into effect. Therefore, although there is an advantage that the characteristic frequency of the main filter is hardly shifted by a power variation and a temperature fluctuation, there has been a problem that the power consumption is comparatively large since the power consumptions of the reference filter 2, the phase difference comparator 3 and the control voltage generator 4 shown in FIG. 10, which is not required for proper wireless communication is wastefully used.

Moreover, according to the filter automatic adjustment method of the second prior art, the adjustment result is stored into the register 18 shown in FIG. 11, and therefore, it is superior to the adjustment of the first prior art in the point that a low power consumption can be achieved by turning off the power supply to the circuits 12 to 17 required for the filter adjustment if adjustment is once performed.

However, when there is a plurality of main filters to be adjusted and a plurality of types of devices are properly used for the filters in accordance with the respectively required specifications in such a manner that the capacitance is configured to include a MOS capacitor (Metal-Oxide-Semiconductor capacitor) and a MOM capacitor (Metal-Oxide-Metal capacitor) and the resistance is configured to include a polysilicon resistor (hereinafter referred to as a PS resistor) and a diffused resistor, variations generated in the manufacturing processes are severally different, and therefore, the same number of reference filters as the combinations of CR products used in the main filter is necessary, and this leads to an areal increase.

Moreover, even if capacitors and resistors of the same types are used, it is often the case where capacitors and resistors of different shapes are used when a plurality of main filters of different cutoff frequencies are used. When the shapes of the resistors and capacitors are largely varied, it causes adjustment errors if CR product variation correction is uniformly performed.

FIG. 15 is a simple schematic longitudinal sectional view of a PS resistor for explaining the problem of the filter automatic adjustment circuit of FIG. 11.

Referring to FIG. 15, the resistance value of the main filter is determined from the wiring 51 to which another element is connected, a PS portion 52 and contact portions 53 to connect them, and the resistance value becomes a total of the resistance values of these elements. It is assumed that another device is located near the PS portion 52 and the resistance value of the wiring 51 is a value that can be ignored. In order to reduce the resistance value of the main filter, the resistance value can be reduced by shortening the main body of the PS portion 52 as shown in FIG. 15(a), and the rate of the contact portions 53 is increased with regard to the resistance value. On the other hand, in order to increase the resistance value of the main filter, the resistance value is increased by lengthening the main body of the PS portion 52 as shown in FIG. 15(b), and therefore, the rate of the contact portion 53 is reduced with regard to the resistance value.

FIG. 16 is a table showing an example of the manufacturing process variation of the PS resistors of different shapes for explaining the problem of the filter automatic adjustment circuit of FIG. 11. In this case, trial calculations when the PS portion 52 and the contact portion 53 are varied in the manufacturing processes in two PS resistors R1 and R2 of which the resistance values of the main filters are largely different are described with reference to FIG. 16. The PS resistor R1 has a resistance of 100Ω, and the PS resistor R2 has a resistance of 1000Ω. Regarding these compositional items, the PS resistor R1 is configured to include 80Ω of the PS portion 52 and 20Ω of the contact portions 53, and the PS resistor R2 is configured to include 980Ω of the PS portion 52 and 20Ω of the contact portions 53. Postulating that the PS portion 52 varies by +10% and the contact portion 53 varies by −10% due to manufacturing process variations, then the PS resistor R1 has a resistance of 106Ω and the PS resistor R2 has a resistance of 1096Ω, and this means that the PS resistor R2 has a variation of +9.6% of the design value in contrast to the fact that the PS resistor R1 has a variation of +6.0% of the design value, as shown in FIG. 16.

FIG. 17 is a table showing an example of the adjustment error when PS resistors of different shapes are used for explaining the problem of the filter automatic adjustment circuit of FIG. 11. Trial calculations when the filter adjustment is performed according to the second prior art by using these PS resistors R1 and R2 are described with reference to FIG. 17.

In order to adjust the main filter F1, the reference filter is provided by a PS resistor (PS resistor R1 of FIG. 16) similar to the main filter F1, and the main filter F2 is provided by another PS resistor (PS resistor R2 of FIG. 16). It is postulated that the PS resistor 52 varies in the manufacturing processes in a manner similar to that of the aforementioned case. Consideration is made on the assumption that there is no capacitance variation for simplicity of the problem, the CR product variation of the reference filter becomes +6.0%, and therefore, the ideal correction coefficient becomes 0.9434. If the main filter is adjusted by the correction coefficient, the CR product variation of the main filter F1 is adjusted to ±0%. However, in the case of the main filter F2, the CR product variation is disadvantageously adjusted to +3.4%, causing an adjustment error. There is a method for using a plurality of resistors connected in series or in parallel with a resistor of the same shape used as a base in the main filter F1 and the main filter F2 in order not to cause an adjustment error. Although no adjustment error occurs if this method is used, it still causes an area increase.

### SUMMARY OF THE INVENTION

An object of the present invention is to solve the aforementioned conventional problems and provide a filter automatic adjustment circuit and method and a wireless communication apparatus, which achieve variation correction with high adjustment accuracy compared to the prior art, making it possible to easily achieve a low current consumption to be in a filter that has an adjustment function of the characteristic frequency based on an output signal from a reference filter and to reliably suppress the filter adjustment error by the variation correction.

In order to achieve the aforementioned objective, according to the first aspect of the present invention, there is provided a filter automatic adjustment adjusting a characteristic frequency of a main filter whose characteristic frequency is adjustable with a reference signal frequency served as a target frequency. The filter automatic adjustment circuit includes a reference filter, a phase difference detector, a counter, a decoder, a plurality of registers, and a plurality of main filters. The reference filter has a plurality of modes that can be selectively changed over, and the reference filter filters an inputted reference signal and outputs a filtered signal. The phase difference detector detects a phase difference between an input signal inputted to the reference filter and an output signal from the reference filter, and outputs a signal having a duty ratio corresponding to a phase difference caused by the reference filter. The counter counts a duty ratio corresponding to the phase difference caused by the reference filter based on input signals including the output signal from the phase difference detector and the reference signal, and outputs a signal representing a counted duty ratio. The decoder decodes the output signal from the counter into a control signal for variation correction on the main filter made based on the reference filter. Each of the plurality of registers holds and outputs the control signal outputted from the decoder. Each of the plurality of main filters performs filtering signal processing so as to select the characteristic frequency in accordance with the respective control signals outputted from the plurality of registers. Each of the main filters and the reference filter is an active filter using an operational amplifier, and the reference filter is able to perform mode change.

In the above-mentioned filter automatic adjustment circuit, the reference filter performs the mode change by one of the following:

(a) selective changeover between a MOS (Metal-Oxide-Semiconductor) capacitor and a MOM (Metal-Oxide-Metal) capacitor; and

(b) selective changeover between a MOS capacitor and a MIM (Metal-Insulator-Metal) capacitor.

In addition, in the above-mentioned filter automatic adjustment circuit, the reference filter performs the mode change by selective changeover between a PS (polysilicon) resistor and a diffused resistor.

Further, in the above-mentioned filter automatic adjustment circuit, the reference filter has a phase difference of 90 degrees or −90 degrees to be generated when a signal of the characteristic frequency is given.

Furthermore, in the above-mentioned filter automatic adjustment circuit, the reference filter performs the mode change by selective changeover among a plurality of devices of same type having different shapes.

Still further, in the above-mentioned filter automatic adjustment circuit, the reference filter is able to change the characteristic frequency. Still more further, in the above-mentioned filter automatic adjustment circuit, the reference phase difference detector is an AND circuit.

Further, the above-mentioned filter automatic adjustment circuit further includes a judgment part for performing one of performing readjustment, issuing an output signal of an error indication, and issuing an instruction to use a preceding result, when the adjustment results of the plurality of filters do not conform to a selection condition based on one of the output signal from the counter, the output signal from the decoder, and the output signal from the register.

Furthermore, in the above-mentioned filter automatic adjustment circuit, the main filter is used in place of the reference filter by performing changeover instead of providing the reference filter.

According to the second aspect of the present invention, there is provided a filter automatic adjustment method for adjusting a characteristic frequency of a main filter whose characteristic frequency is adjustable with a reference signal frequency served as a target frequency. The filter automatic adjustment method includes the steps of:

setting a reference filter into a first mode, the reference filter having a plurality of modes that can be selectively changed over, and filtering an inputted reference signal and outputting a filtered signal;

inputting the reference signal to the reference filter;

counting a duty ratio between an input signal inputted to the reference filter and an output signal from the reference filter in the first mode, and outputting a count number;

decoding the count number into a decoded value in the first mode;

storing the decoded value into a first register in the first mode;

setting the reference filter into a second mode;

counting a duty ratio between the input signal inputted to the reference filter and the output signal from the reference filter in the second mode, and outputting a count number;

decoding the count number in the second mode into a decoded value; and

storing the decoded value into a second register in the second mode.

The filter automatic adjustment method further includes a step of changing the frequency of the reference signal inputted to the reference filter when a changeover from the first mode to the second mode is performed.

In addition, the filter automatic adjustment method further includes a step of counting the duty ratio between the input signal inputted to the reference filter and the output signal from the reference filter in the second mode, outputting a count number, then judging adjustment results based on one of the count numbers, the decoded values, and the output signals from the first and second register in the first mode and the second mode, and performing one of readjustment, issuing an output signal of an error indication and using a preceding result when the adjustment results do not conform to a selection condition.

Further, the filter automatic adjustment method further includes a step of writing one of the count numbers, the decoded values, and the output signals from the first and second registers into a nonvolatile memory in a manufacturing process of a wireless communication apparatus.

According to the third aspect of the present invention, there is provided a wireless communication apparatus including a main filter, and a baseband signal processing part. The main filter filters a signal inputted from an antenna, and the main filter has been undergone filter adjustment by a filter automatic adjustment circuit to remove interference waves of frequencies different from a target frequency. The baseband signal processing part inputs the signal from which the interference waves have been removed from the main filter, and converts the signal into audio and data. The filter automatic adjustment circuit is provided for adjusting a characteristic frequency of a main filter whose characteristic frequency is adjustable with a reference signal frequency served as a target frequency.

The filter automatic adjustment circuit includes a reference filter, a phase difference detector, a counter, a decoder, a plurality of registers, and a plurality of main filters. The reference filter has a plurality of modes that can be selectively changed over, and the reference filter filters an inputted reference signal and outputting a filtered signal. The phase difference detector detects a phase difference between an input signal inputted to the reference filter and an output signal from the reference filter, and outputs a signal having a duty ratio corresponding to a phase difference caused by the reference filter. The counter counts a duty ratio corresponding to the phase difference caused by the reference filter based on input signals including the output signal from the phase difference detector and the reference signal, and outputs a signal representing a counted duty ratio. The decoder decodes the output signal from the counter into a control signal for variation correction on the main filter made based on the reference filter. Each of the plurality of registers holds and outputs the control signal outputted from the decoder. Each of the plurality of main filters performs filtering signal processing so as to select the characteristic frequency in accordance with the respective control signals outputted from the plurality of registers. Each of the main filters and the reference filter is an active filter using an operational amplifier. The reference filter is able to perform mode change.

In the above-mentioned wireless communication apparatus, the wireless communication apparatus is a portable telephone system.

Therefore, according to the invention, the reference filter, capable of changing the resistance and the capacitor in accordance with the main filter to be adjusted when a variation in the reference filter is detected, is provided for a plurality of main filters, and this leads to that the characteristic frequencies of the plurality of main filters can be adjusted with high accuracy. By holding in a register the adjustment result as a control signal for the filter to be adjusted, all the operations of the members relevant to the filter adjustment can be stopped after the filter variation correction. Therefore, the filter that has the adjustment function of the characteristic frequency based on the output signal from the reference filter can be subjected to the variation correction that has high adjustment accuracy, and easily achieves a low current consumption, and filter adjustment errors can reliably be suppressed by the variation correction.

Moreover, for the reason that the main filter and the reference filter are active filters employing an operational amplifier, the active filter employing the operational amplifier has its characteristic frequency determined almost only by the resistance and the capacitance, and therefore, it is tolerant to power variation and temperature fluctuation, which is very convenient for the invention that holds the result adjusted only once.

Further, the reference filter has a phase difference of 90 degrees or −90 degrees generated when a signal of the characteristic frequency is given. With this arrangement, an AND circuit can be used for the phase difference detector when the phase difference of the reference filter becomes 90 degrees or −90 degrees, and the circuit scale can be reduced.

Furthermore, mode change of the reference filter is performed by selective changeover between the MOS capacitor and the MOM capacitor or between the MOS capacitor and the MIM capacitor (Metal-Insulator-Metal Capacitor). With this arrangement, the integrated circuit can be further reduced in size by proper use in such a manner that the MOS capacitor having a large unit capacitance is used for the main filter desired to be reduced in size and the MOM capacitor or the MIM capacitor is used for the main filter desired to be tolerant to the power variation and the temperature fluctuation.

Moreover, the reference filter performs mode change by selective changeover between the PS resistor and the diffused resistor. By this operation, the integrated circuit can be further reduced in size by proper use in such a manner that the diffused resistor of a small unit resistance is used when the resistance value of the main filter is desired to be reduced or the PS resistor of a great unit resistance is used when the resistance value of the main filter is desired to be increased.

Further, the reference filter performs mode change by selective changeover between the plurality of devices of the same type and different shapes. By this operation, the shapes of the resistors and the capacitors used in the plurality of main filters can freely be selected, and the integrated circuit can consequently be reduced in size.

Furthermore, the reference filter can change the characteristic frequency. With this arrangement, the adjustment accuracy can be changed for each main filter when the required adjustment accuracy differs depending on the plurality of main filters, and the integrated circuit can consequently be further reduced in size.

Moreover, the reference phase difference detector is the AND circuit. With this arrangement, the filter automatic adjustment circuit can be made simpler, and the integrated circuit can consequently be further reduced in size.

Further, by providing the judgment part for issuing an instruction for performing readjustment or outputting an output signal of an error indication or using the preceding result when the result does not conform to the selection condition regarding the plurality of filter adjustment results based on any one of the count number, the decoded value and the output signal from the register, the reliability of the adjustment result of the filter automatic adjustment circuit can be increased.

Furthermore, by performing the changeover operation without providing the reference filter, the main filter is used in place of the reference filter. With this arrangement, there is merit of a size reduction by virtue of non-provision of the reference filter and a merit of removing the relative errors of the reference filter and the main filter.

Moreover, any one of the count number, the decoded value and the output signal from the register is written into a nonvolatile memory in the manufacturing process of the wireless communication apparatus. By this operation, the wireless communication apparatus is allowed to have low power consumption because of non-necessity of performing again the filter adjustment even when the power of the wireless communication apparatus is turned off and turned on again.

Further, according to the wireless communication apparatus having the aforementioned filter automatic adjustment circuit, variation correction that has high adjustment accuracy and easily achieves a low current consumption is made possible in a portable telephone system that requires particularly a low power consumption and a size reduction, and the filter adjustment error can reliably be suppressed by the variation correction.

### BRIEF DESCRIPTION OF THE DRAWINGS

These and other objects and features of the present invention will become clear from the following description taken in conjunction with the preferred embodiments thereof with reference to the accompanying drawings throughout which like parts are designated by like reference numerals, and in which:

FIG. 1 is a block diagram showing a configuration of a filter automatic adjustment circuit according to a first preferred embodiment of the invention;

FIG. 2 is a schematic waveform chart of output signals of blocks in the filter adjustment operation of the filter automatic adjustment circuit of FIG. 1;

FIG. 3 is a schematic waveform chart of output signals of the blocks in the filter adjustment operation of the filter automatic adjustment circuit of FIG. 1;

FIG. 4 is a circuit diagram showing a detailed configuration of the reference filter 103 of FIG. 1;

FIG. 5 is a flow chart showing a filter adjustment process which is executed by the filter automatic adjustment circuit of FIG. 1;

FIG. 6 is a table showing relations between the CR product variation of the reference filter 103 and the count number in the filter automatic adjustment circuit of FIG. 1;

FIG. 7 is a block diagram showing a configuration of a filter automatic adjustment circuit according to a second preferred embodiment of the invention;

FIG. 8 is a flow chart showing a filter adjustment process executed by the filter automatic adjustment circuit of FIG. 7;

FIG. 9 is a block diagram showing a structural example of a portable telephone system according to a third preferred embodiment of the invention;

FIG. 10 is a block diagram showing a configuration of a filter automatic adjustment circuit according to the first prior art;

FIG. 11 is a block diagram showing a configuration of a filter automatic adjustment circuit according to the second prior art;

FIG. 12 is a circuit diagram showing one example of the reference filter 13 of FIG. 11;

FIG. 13 is a timing chart for explaining the filter adjustment operation of the filter automatic adjustment circuit of FIG. 11;

FIG. 14 is a table showing relations between the CR product variation of the reference filter 13 and the count number in the filter adjustment operation of the filter automatic adjustment circuit of FIG. 11;

FIG. 15 is a simple schematic longitudinal sectional view of a PS resistor for explaining a problem of the filter automatic adjustment circuit of FIG. 11;

FIG. 16 is a table showing an example of the manufacturing process variation of PS resistors of different shapes for explaining a problem of the filter automatic adjustment circuit of FIG. 11; and

FIG. 17 is a table showing an example of adjustment errors when the PS resistors of different shapes are used for explaining a problem of the filter automatic adjustment circuit of FIG. 11.

### DETAILED DESCRIPTION OF THE PREFERRED EMBODIMENTS

Preferred embodiments of the invention will be described below with reference to the drawings. It is noted that like components are denoted by like reference numerals in the following preferred embodiments.

### First Preferred Embodiment

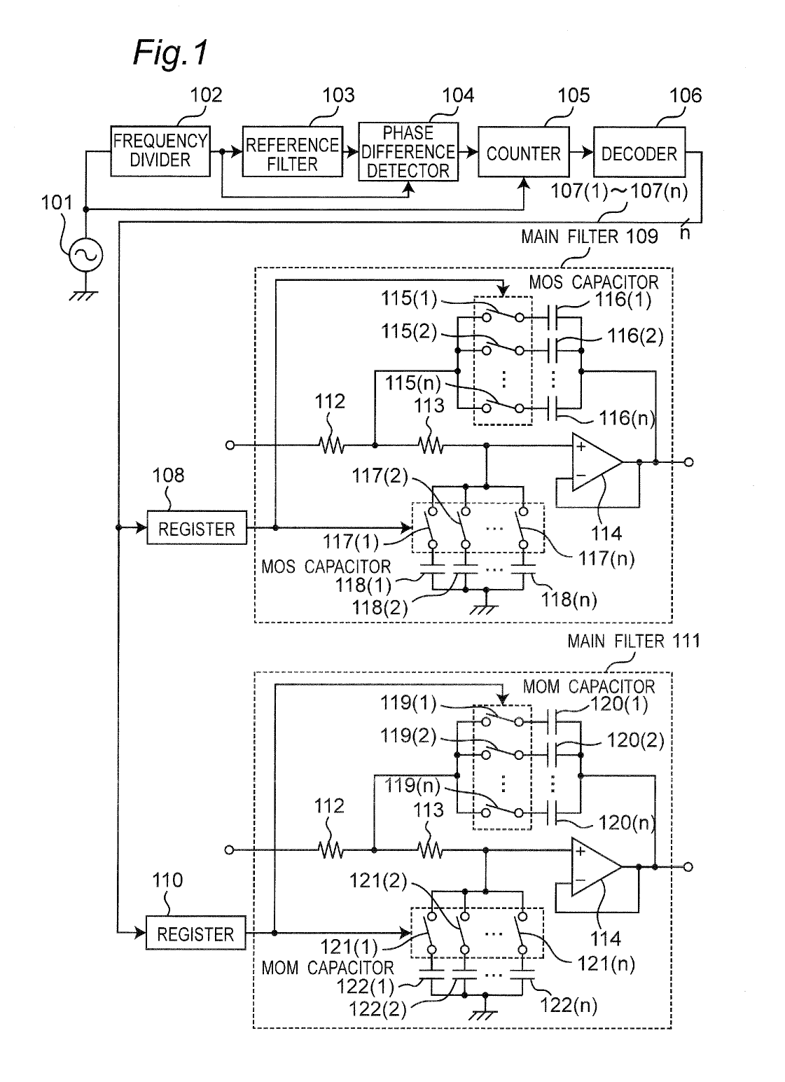

FIG. 1 is a block diagram showing a configuration of a filter automatic adjustment circuit according to the first preferred embodiment of the invention. Referring to FIG. 1, the filter automatic adjustment circuit of the present preferred embodiment is configured to include a reference signal generator 101, a frequency divider 102, a phase difference detector 104, a counter 105, a decoder 106, registers 108 and 110, and main filters 109 and 110. The main filter 109 is, for example, an active filter configured to include input resistors 112 and 113, an operational amplifier 114, changeover switches 115(1) to 115(n), MOS capacitors 116(1) to 116(n) that are feedback capacitors, changeover switches 117(1) to 117(n) and MOS capacitors 118(1) to 118(n) that are input capacitors. Further, the main filter 111 is, for example, an active filter configured to include input resistors 112 and 113, an operational amplifier 114, changeover switches 119(1) to 119(n), MOM capacitors 120(1) to 120(n) that are feedback capacitors, changeover switches 121(1) to 121(n) and MOM capacitors 122(1) to 122(n) that are input capacitors.

The reference filter 103 of FIG. 1 is not to actually perform filtering process of a signal but to detect a variation in the device constant of a semiconductor integrated circuit of an integration of the present filter automatic adjustment circuit, and the variation mentioned in this case means principally the resistance variation and the capacitor variation at the semiconductor integrated circuit manufacturing time.

The reference filter 103 of FIG. 1 is an LPF configured to include, for example, an active filter as shown in FIG. 4. Referring to FIG. 4, the reference filter 103 is configured to include input resistors 141 and 142, an operational amplifier 143, a changeover switch 144, a MOS capacitor 145, a MOM capacitor 146, a changeover switch 147, a MOS capacitor 148 and a MOM capacitor 149. In this case, when a reference signal having the characteristic frequency of the reference filter 103 is inputted to the reference filter 103, a phase difference between an input waveform and an output waveform is designed to become 90 degrees. When there are the resistance variation and the capacitance variation as described above, the phase difference takes a value different from 90 degrees. In this case, by performing selective changeover by the changeover switches 144 and 147, selective changeover between a mode in which the MOS capacitors 145 and 148 are used and a mode in which the MOM capacitors 146 and 149 can be used and set. It is noted that a MIM (Metal-Insulator-Metal) capacitor may be used in place of the MOM capacitors 146 and 149.

The reference signal outputted from the reference signal generator 101 is inputted to the counter 105 and inputted to the reference filter 103 and the phase difference detector 104 via the frequency divider 102. Subsequently, the frequency divider 102 generates a signal that has a signal waveform duty ratio of 50% and the characteristic frequency of the reference filter 103 by dividing the inputted reference signal, and outputs the signal to the reference filter 103 and the phase difference detector 104. That is, the output signal and the input signal of the reference filter 103 are inputted to the phase difference detector 104, and the phase difference detector 104 detects a phase difference between the inputted two signals and outputs a signal that represents the detection result to the counter 105. In the present preferred embodiment, the phase difference detector 104 is configured to include the AND circuit. The counter 105 counts the duty ratio by counting the pulses of the output signal of the phase difference detector 104 based on the reference signal and outputs a signal that represents it.

In the present preferred embodiment, the signal that has the signal waveform duty ratio of 50% and the characteristic frequency of the reference filter 103 by is generated by dividing the reference signal outputted from the reference signal generator 101 by the frequency divider 102. However, the invention is not limited to this, and when the characteristic frequency of the reference filter 103 and the frequency of the signal outputted from the reference signal generator 101 are the same, there is no specific need to provide the frequency divider 102, and the reference signal outputted from the reference signal generator 101 may be directly inputted to the reference filter 103.

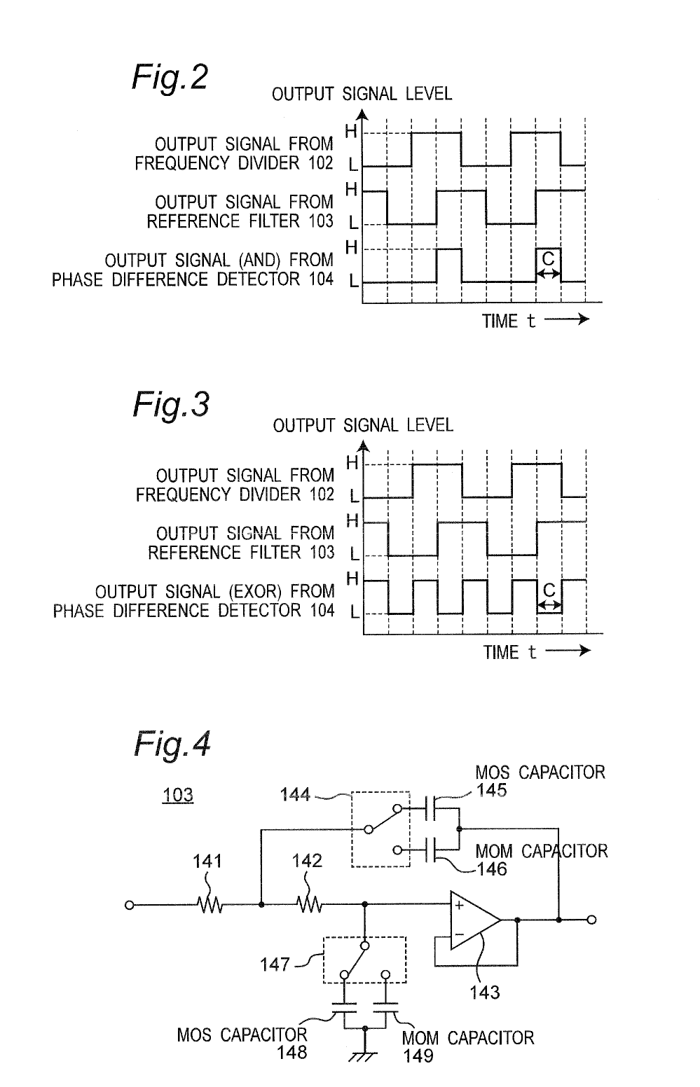

FIG. 2 is a schematic waveform chart of the output signals of blocks in the filter adjustment operation of the filter automatic adjustment circuit of FIG. 1. If one example of the operation is described with reference to FIG. 2, the output signal of the frequency divider 102 is a square wave having a duty ratio of 50%, and the output signal of the reference filter 103 has its phase delayed by 90 degrees compared to the output signal of the frequency divider 102. An output signal when the output signal of the frequency divider 102 and the output signal of the reference filter 103 are inputted to the phase difference detector 104 has the waveform of the output signal (AND) of the phase difference detector 104.

FIG. 13 is a timing chart for explaining the filter adjustment operation of the filter automatic adjustment circuit of FIG. 11, and FIG. 14 is a table showing relations between the CR product variation of the reference filter 13 and the count number in the filter adjustment operation of the filter automatic adjustment circuit of FIG. 11. A method for judging the CR product variation from the output signal of the phase difference detector 104 is described below with reference to FIGS. 13 and 14.

FIG. 13 shows a state in which the output signal of the phase difference detector 104 is counted by the counter 105. When H-level intervals of the output signal of the phase difference detector 104 are counted at timings when the reference signal rises, the count number is eight when there is no CR product variation (CR product=±0%), and the count number is ten when there is a CR product variation (CR product=−26%).

FIG. 14 shows one example of the relations between the CR product variation and the count number when the output signal of the phase difference detector 104 is counted in FIG. 13. If the CR product of the capacitor and resistance varies, the phase of the output signal of the reference filter 103 shifts from the phase difference of 90 degrees compared to the waveform of the input of the reference filter 103, and the duty ratio of the output signal of the phase difference detector 104 consequently changes as shown in FIG. 13. By selecting the MOS capacitors 116(1) to 116 (n) and 118(1) to 118(n) or the MOM capacitors 120(1) to 120(n) and 122(1) to 122(n) in accordance with the count number by selective changeover of their connections with the changeover switches 115(1) to 115(n) and 117(1) to 117(n) or the changeover switches 119(1) to 119(n) and 121(1) to 121(n) based on FIG. 14, the apparent CR product variations of the capacitors and the resistors in the main filters 109 and 111 can be reduced.

For example, it can be understood that the CR product variation ranges from −13.1% to −25% from FIG. 14 when the count number is nine. Therefore, in the above case, by selecting a value obtained by multiplying the capacitance value 1.235 times that of the normal design, the apparent CR product variation by the correction can be made 7.4% to −7.4%. The CR product variation (causing the characteristic variation) can be adjusted to be suppressed for the main filters 109 and 111. The main filters 109 and 111 of FIG. 1 are active filters employing operational amplifiers. This form has a feature that it is tolerant to the power voltage variation and the temperature fluctuation when once adjusted since the frequency characteristic of the filter depends almost on the resistance and the capacitance.

Although it has been described that the reference filter 103 has its phase shifted by 90 degrees when there is no CR product variation in the present preferred embodiment, it is essentially required that the CR product variation and the phase difference has a definite relation (e.g., −90 degrees) even in a case other than 90 degrees.

Moreover, although the phase difference detector 104 employs the AND circuit, the invention is not limited to this, and another circuit like the EXOR circuit shown in FIG. 3 may be employed so long as it is a circuit that can judge the phase difference between the output signal and the input signal of the reference filter 103.

Next, a method for adjusting the plurality of main filters 109 and 111 is described. The present configuration has the two main filters 109 and 111, where the characteristic frequency of the main filter 109 is obtained by the CR product of the PS resistor and the MOS capacitor, and the characteristic frequency of the main filter 111 is obtained by the CR product of the PS resistor and the MOM capacitor. The two main filters are designed by using different capacitors since the required performances (e.g., power voltage variation characteristic, area etc.) are different from each other.

First of all, upon adjusting the main filter 109, the switch 144 of the reference filter 103 is selectively changed over for connection to the MOS capacitor 145. Likewise, the switch 147 of the reference filter is selectively changed over for connection to the MOS capacitor 148. In the above condition, a signal having the characteristic frequency of the reference filter 103 is inputted with a signal waveform duty ratio of 50% to the reference filter 103, and the input signal and the output signal of the reference filter 103 are inputted to the phase difference detector 104. The output signal of the phase difference detector 104 is counted by the counter 105. At this time, idle operation is performed so that the reference filter 103 stably operates, and the repetition of the H level and the low level (hereinafter referred to as an L level) of the output signal from the phase difference detector 104 is counted several times. When the counting of a supposed frequency is completed, then the intervals when the phase difference detector 104 becomes the H level are next counted by the counter 105. The decoder 106 outputs capacitor changeover signals 107(1) to 107(n) for correcting the CR product variation of the PS resistor and the MOS capacitor in accordance with the count number, and the signals are stored into the register 108. The capacitor changeover switches 115(1) to 115(n) and 117(1) to 117(n) of the main filter 109 are changed over in accordance with the results stored in the register 108, and setting is performed by selection among the MOS capacitors 116(1) to 116(n) and 118(1) to 118(n) corresponding to the adjustment results. That is, the decoder 106 decodes the control signal for the variation correction of the main filters 109 and 111 based on the reference filter 103 and outputs the capacitor changeover signal.

Next, upon adjusting the main filter 111, the switch 144 of the reference filter is changed over for connection to the MOM capacitor 146. Likewise, the switch 147 of the reference filter is changed over for connection to the MOM capacitor 149. Then, idle operation is performed in a manner similar to that of the adjustment of the main filter 109, and subsequently the H-level intervals of the output signal of the phase difference detector 104 are counted by the counter 105. The decoder 106 outputs the capacitor changeover signals 107(1) to 107(n) for correcting the CR product variation of the PS resistor and the MOM capacitor in accordance with the count number, and the signals are stored into the register 110. The capacitor changeover switches 119(1) to 119(n) and 121(1) to 121(n) of the main filter 111 are changed over by the results stored in the register 110, and selection of MOM capacitors 120(1) to 120(n) and 122(1) to 122(n) corresponding to the adjustment results is performed.

Although it has been described that the main filter 109 and the main filter 111 are configured to include the combination of the PS resistor and the MOS capacitor and the combination of the PS resistor and the MOM capacitor, respectively, in the present preferred embodiment, the present invention is limited neither to this nor required to be limited to the combinations. It is possible to accurately adjust the characteristic frequency of the plurality of main filters by changeover among the combinations of the capacitors and the resistors of the types and shapes used in the main filter by the reference filter in the plurality of main filters of different types and shapes of the capacitors and resistors. In addition, the main filters can be adjusted by changeover with the reference filter even in a configuration including an inductor without being limited to the configuration made up of the capacitors and the resistors. Moreover, in order to perform highly accurate counting, it is acceptable to adopt a method for taking an average or a mode value by performing counting a plurality of times or a method for taking an average or a mode value by performing counting with a plurality of reference signals of different phases.

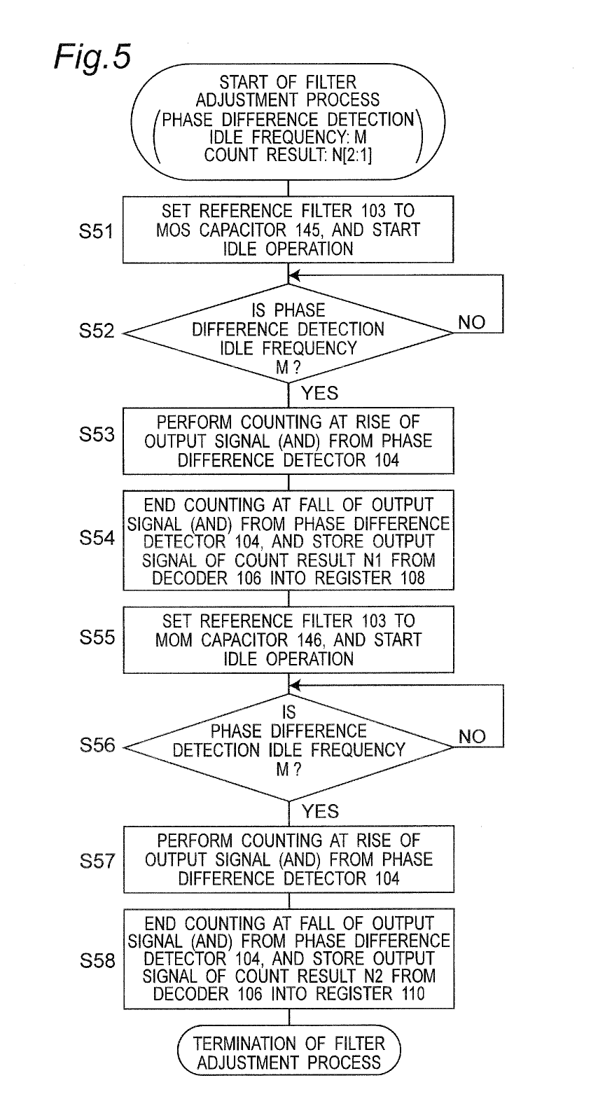

FIG. 5 is a flow chart showing a filter adjustment process which is executed by the filter automatic adjustment circuit of FIG. 1. The filter adjustment process is described below with reference to the flow chart of FIG. 5. It is assumed that the phase difference detection idle frequency is M, and the count result is N that can take a value of one or two.

Referring to FIG. 5, upon receiving a filter adjustment start instruction, the reference filter 103 is set to the MOS capacitor 145, and the idle operation is performed by turning on the power of the circuits 101 to 106 required for the filter adjustment (at step S51). Next, it is awaited until the output signal of the reference filter 103 becomes stable (at step S52). In this case, although the frequency of changes from the L level to the H level of the output signal of phase difference detector 104 is counted and the program flow proceeds to the next step when the count number becomes M, another method is acceptable such as provision of a timer circuit or the like. Next, the intervals when the output signal of the phase difference detector 104 has the H level are counted with the reference signal (at step S53). Then, the counting is ended when the output signal of the phase difference detector 104 becomes the L level from the H level, and a MOS capacitor changeover signal is outputted from the decoder in accordance with the count result and stored into the register 108 (at step S54). The output signal from the register 108 holds the result after the filter adjustment ends, and the MOS capacitors (one of 116(1) to 116(n) and one of 118(1) to 118(n)) of the main filter 109 are selected. Next, the reference filter 103 is set to the MOM capacitor 146, and the idle operation is performed (at step S55). Further, in a manner similar to that of the step S52 to step S54, the H-level intervals of the output signal of the phase difference detector are counted with the reference signal, and the decoded result is stored into the register 110 (at step S56 to step S58). The MOM capacitors (one of 120(1) to 120(n) and one of 122(1) to 122(n)) of the main filter 111 are selected, and the filter adjustment process is terminated. At the time, the power to the circuits 101 to 106 used only for filter adjustment is turned off to achieve low power consumption.

Although the filter adjustment results are inputted to the registers 108 and 110 in the present preferred embodiment, it is also possible to perform filter adjustment in the manufacturing process of the wireless communication apparatus and to write the adjustment results into a nonvolatile memory. This leads to that it is not necessary to perform filter readjustment even when the power of the wireless communication apparatus is turned off. Moreover, it is also acceptable to change the characteristic frequency when the mode of the reference filter 103 is changed. Although one of the capacitors of the main filter 109 or 111 is selected in the present preferred embodiment, it is acceptable to select a plurality of capacitors in order to achieve a size reduction by reducing the number of capacitors.

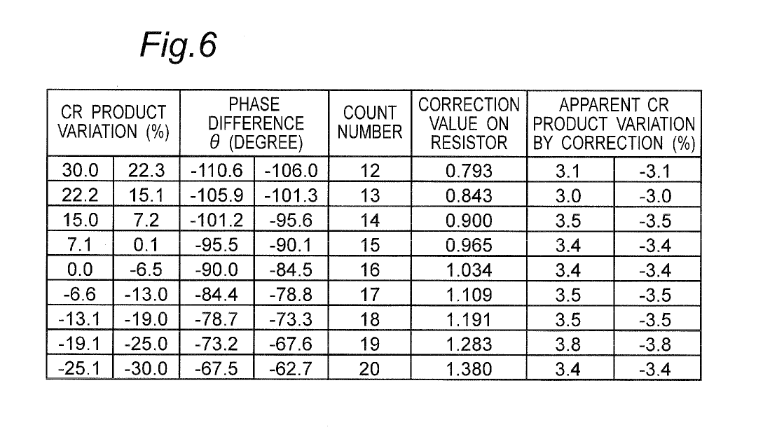

FIG. 6 is a table showing relations between the CR product variation and the count number of the reference filter 103 in the filter automatic adjustment circuit of FIG. 1. That is, FIG. 6 shows one example of relations between the CR product variation and the count number when the characteristic frequency of the reference filter 103 is made half. Since the characteristic frequency of the reference filter 103 is half, the frequency divider 102 performs extra frequency bi-division in comparison with the aforementioned state. In contrast to the fact that the CR product variation after the correction of FIG. 14 is ±7.4% at worst, the CR product variation after the correction shown in FIG. 5 is ±3.8% at worst, meaning that the adjustment error becomes about half. As described above, by dividing half the characteristic frequency of the reference filter 103 or doubling a reference clock 101 for counting, the correction error of the CR product variation can be reduced. Conversely, the number of the capacitors and the resistors to be changed over in accordance with the adjustment results increase leading to an areal increase, and therefore, it is proper to determine the characteristic frequency of the reference filter 103 and the frequency of the reference signal 101 in accordance with the required adjustment accuracy.

Although the reference signal source 101, the frequency divider 102 and the decoder 106 as shown in FIG. 14 are used without any modification upon adjusting the main filter 109 and the main filter 111 of the present preferred embodiment, it is possible to perform modification in accordance with the range of the CR product variation of the plurality of main filters desired to be adjusted and the required adjustment accuracy. That is, it is proper to lower the characteristic frequency of the reference filter 103 or increase the frequency of the reference signal in the case of the main filter that requires high adjustment accuracy or to take a converse measure in the case of a main filter that requires not so high adjustment accuracy. In a case where the adjustment accuracy is changed depending on the main filter to be adjusted, it is proper to perform changeover of the reference signal source 101, the frequency divider 102 and the decoder 106 in accordance with the main filter to be adjusted.

In the case of the adjustment method of the aforementioned first prior art, in which the reference filter always operates, a reference filter besides the main filter for performing the signal processing has been needed. However, since the reference filter 103 is used only at the time of filter adjustment in the present preferred embodiment, it is possible to perform the filter adjustment by using the main filters 109 and 111 in performing the filter adjustment by changeover of the switches and to use the main filters 109 and 111 without any modification for the signal processing by selective changeover of the switches when the adjustment is terminated. As described above, the non-provision of the reference filter 103 has a merit that a further size reduction can be achieved and there is no relative variation of the reference filter 103 and main filters 109 and 111.

### Second Preferred Embodiment

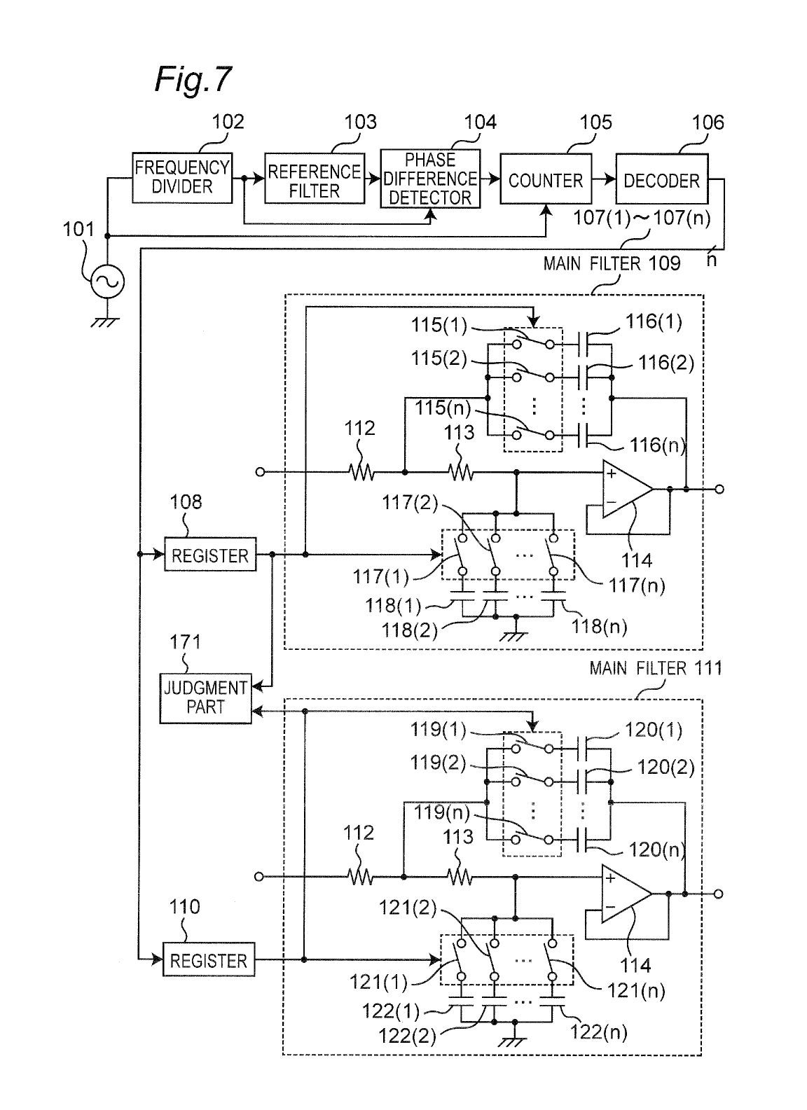

FIG. 7 is a block diagram showing a configuration of a filter automatic adjustment circuit according to the second preferred embodiment of the invention. The filter automatic adjustment circuit of the second preferred embodiment of the invention is characterized in that a method for further increasing the adjustment reliability in comparison with the first preferred embodiment is used, and a judgment part 171 is added in comparison with the block diagram of FIG. 1. Switch changeover signals that are the output signals from the registers 108 and 110 are inputted to the judgment part 171, and the judgment part 171 compares the adjustment result of the main filter 109 with the adjustment result of the main filter 111. If it is judged that the adjustment is not satisfactorily correctly (successfully) performed by using the method described in detail below, the filter adjustment is performed again or an error signal is returned.

The judgment method of the judgment part 171 is described below. Postulating a case where the main filter 109 is configured to include a PS resistor and a MOS capacitor and the main filter 111 is configured to include a diffused resistor and a MOM capacitor and assuming that the manufacturing variations of the resistors and the capacitors of both the filters 109 and 111 are each ±10%, then the CR product variation of both the filters becomes +21% to −19%, possibly causing a case where the CR product variation of the main filter 109 is +21%, the CR product variation of the main filter 111 is −19% and a difference in the CR product variation between the main filter 109 and the main filter 111 becomes 40%. However, when the resistors used in the main filter 109 and the main filter 111 are both common PS resistors, the difference in the CR product variation between the main filter 109 and the main filter 111 becomes smaller than 40%.

In concrete, assuming that both the filters 109 and 111 are the PS resistors of the same shape and there is no relative variation, then the difference in the CR product variation between the main filter 109 and the main filter 111 becomes maximized at 20% when the MOS capacitor of the main filter 109 becomes +10% (or −10%) and the MOM capacitor of the main filter 111 becomes −10% (or +10%). According to FIG. 14, when the difference in the CR product variation between the main filter 109 and the main filter 111 is 20% at most, a difference in the count at the time of adjustment of the main filter 109 and the main filter 111 becomes smaller than two. Therefore, in a case where the difference in the count number is three between when the main filter 109 is adjusted and when the main filter 111 is adjusted, it can be judged that the adjustment result is not correct. As described above, when the main filters 109 and 111 having the plurality of modes are adjusted, the judgment part 171 judges that the adjustment has not been satisfactorily correctly (successfully) performed and performs the filter adjustment again or returns the error signal. It is also acceptable to use the preceding result.

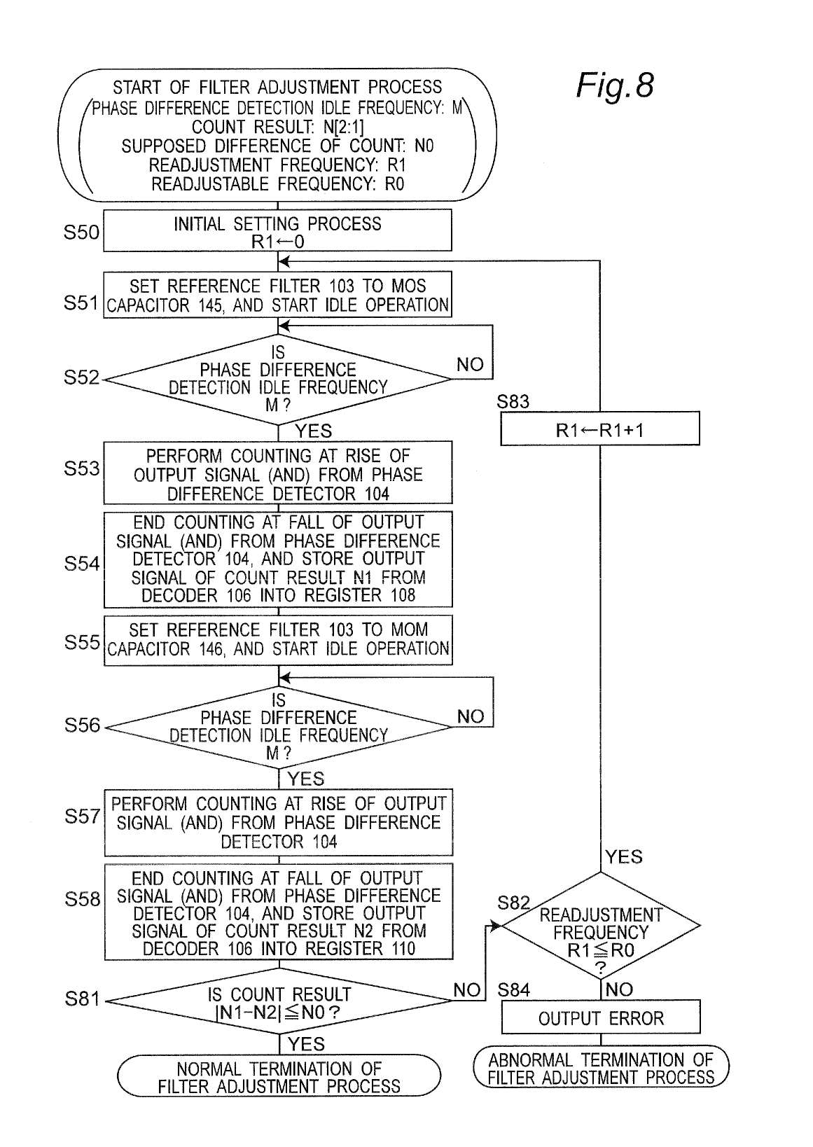

FIG. 8 is a flow chart showing a filter adjustment process which is executed by the filter automatic adjustment circuit of FIG. 7. An example of the judgment operation of the judgment part 171 is described below with reference to the flow chart of FIG. 8.

Referring to FIG. 8, an initial setting process for resetting a readjustment frequency R1 to zero is first executed (at step S50), and after processes similar to those of step S51 to step S58 of FIG. 5 are executed, the adjustment results of the main filter 109 and the main filter 111 are compared with each other. In this case, it is judged whether or not a difference |N1−N2| in the count number between the two adjustment times is not greater than a supposed value N0 (at step S81), and it is assumed that the filter adjustment has been normally terminated when the value is not greater than N0. Conversely, when the difference |N1−N2| in the count number between the two adjustment times is greater than the supposed value N0 (at step S81), readjustment is to be performed. The readjustment frequency R1 is stored (R1 is incremented by one in step S83), and it is judged whether or not the readjustment frequency R1 is not greater than a supposed frequency R0 (at step S82). When the frequency is smaller than the supposed frequency R0, the filter adjustment is performed again from step S51. When the frequency is greater than the supposed frequency R0, an error is outputted (at step S84), and the filter adjustment is terminated. If there is a precedently adjusted result in this case, the adjustment result may be adopted.

Although the judgment part 171 makes a judgment based on the output signals from the registers 108 and 110 in the above second preferred embodiment, the invention is not limited to this but allowed to make a judgment based on the output signal from the counter 105 or 106.

### Third Preferred Embodiment

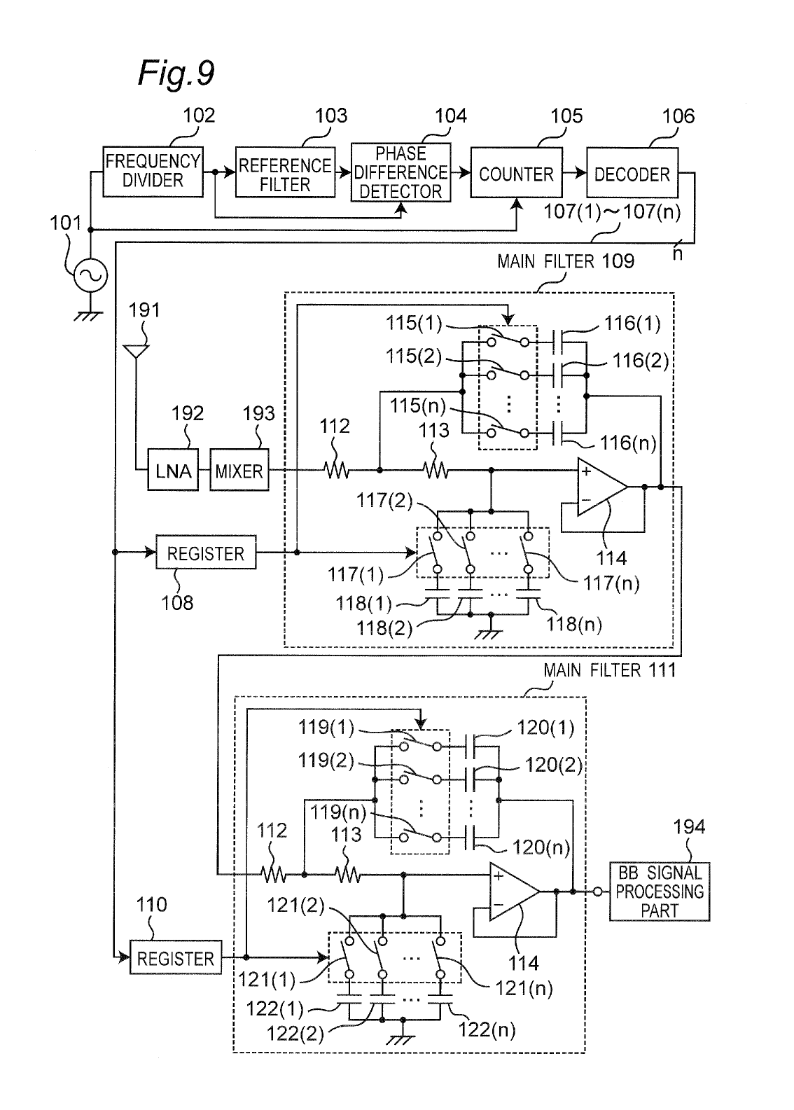

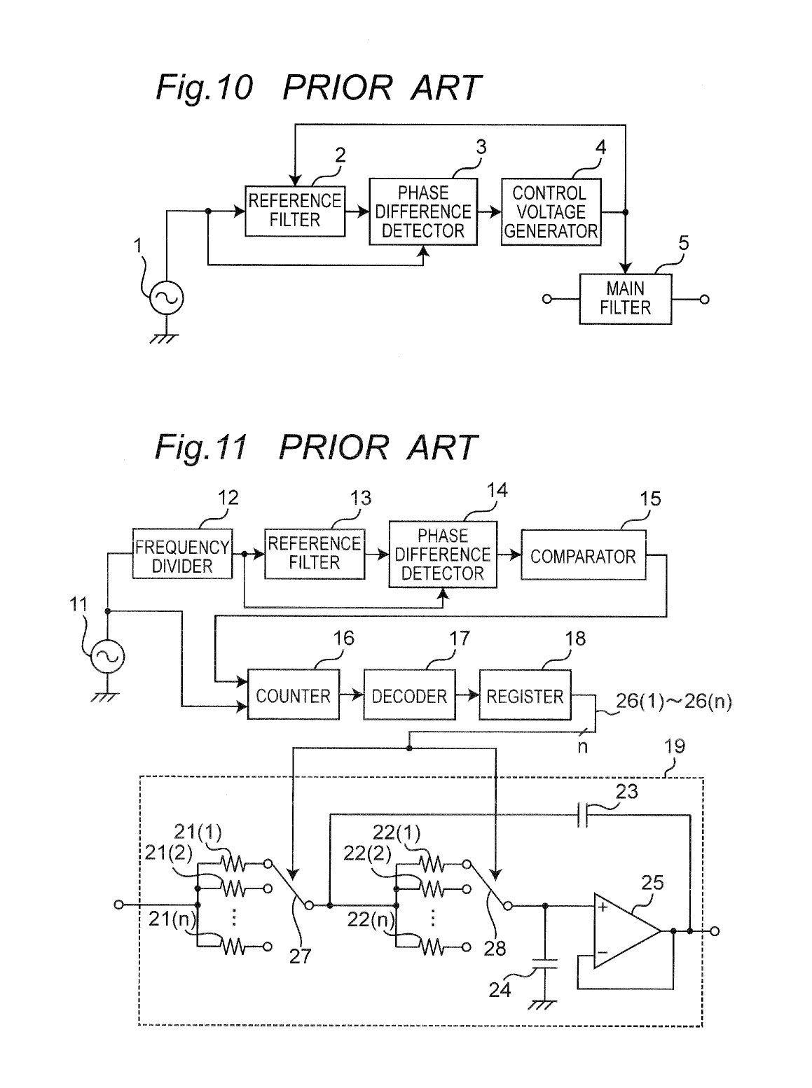

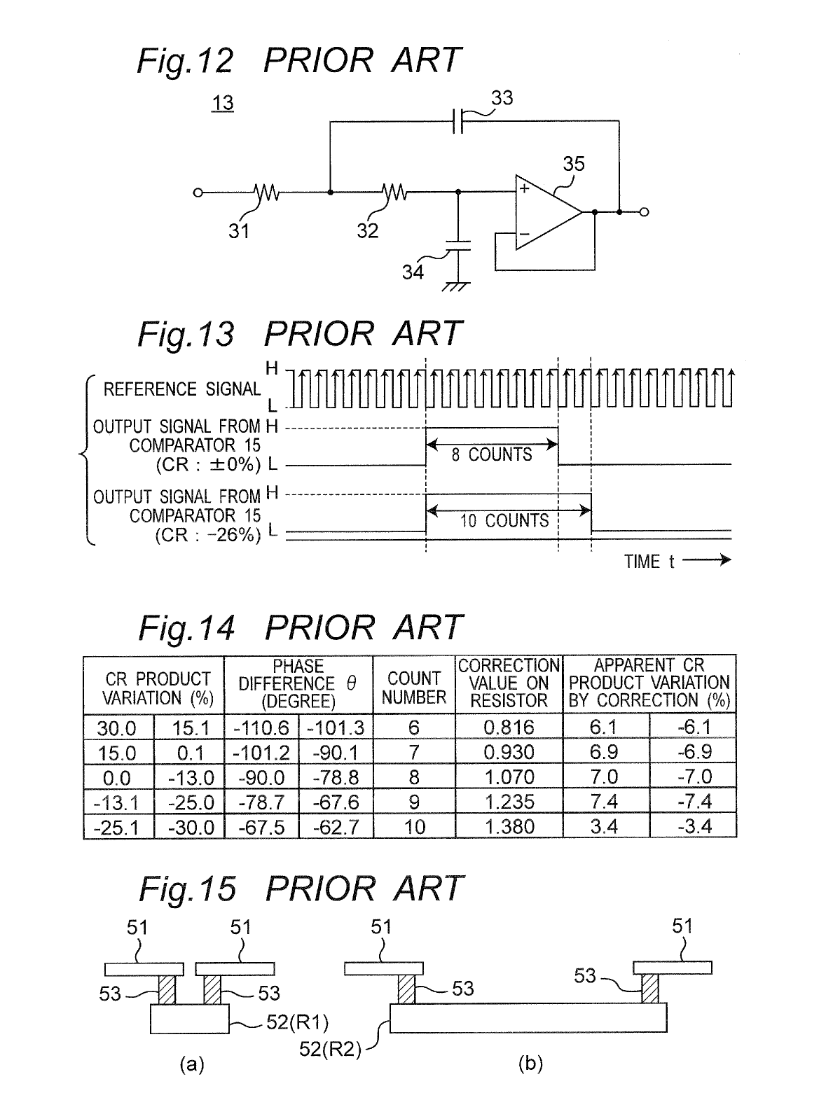

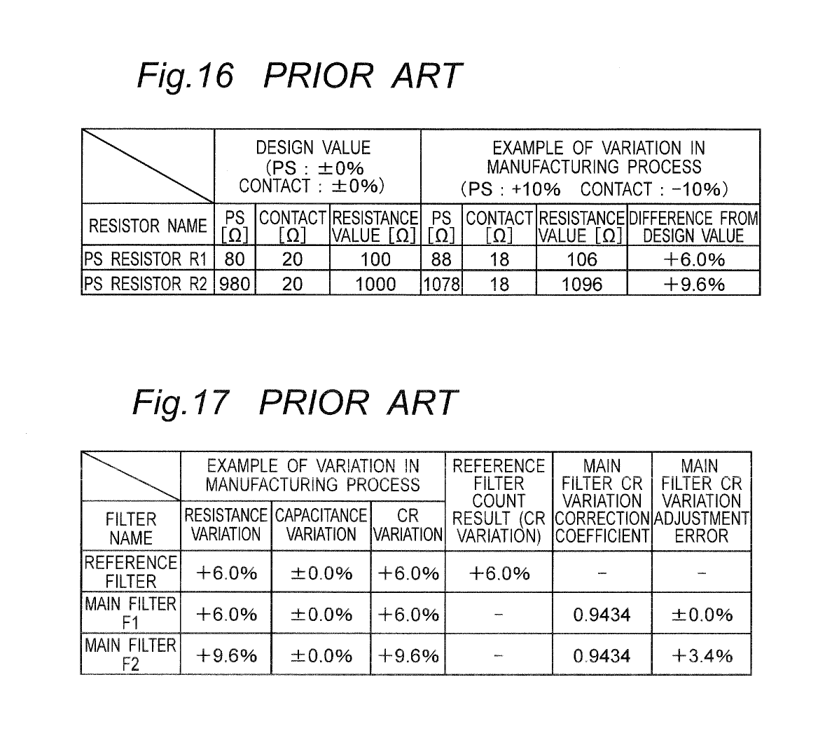

FIG. 9 is a block diagram showing a structural example of a portable telephone system according to the third preferred embodiment of the invention. In the present preferred embodiment, one example of a case where the configuration of the filter automatic adjustment circuit of each of the preferred embodiments is applied to the portable telephone system. Referring to FIG. 9, components similar to those of FIGS. 1 and 7 are denoted by same reference numerals, and no description is provided for them.

Referring to FIG. 9, by amplifying a wireless signal inputted from an antenna 191 by a low-noise amplifier 192 and down-converting the same signal by a mixer 193, the signal is converted into a baseband signal having a baseband frequency, and the baseband signal is filtered by the main filters 109 and 111 (connected together in cascade) adjusted as described above, removing interference waves at frequencies different from the target frequency. The signal, from which the interference waves have been removed, is inputted from the main filter 111 to a baseband signal processing part (BB signal processing part) 194 and converted to a sound or data in the baseband signal processing part 194.

Although the configuration of the portable telephone is described in the above third preferred embodiment, the invention is not limited to this but allowed to be widely applied to wireless communication apparatuses.

Although the present invention has been fully described in connection with the preferred embodiments thereof with reference to the accompanying drawings, it is to be noted that various changes and modifications are apparent to those skilled in the art. Such changes and modifications are to be understood as included within the scope of the present invention as defined by the appended claims unless they depart therefrom.

1. A filter automatic adjustment circuit for adjusting a characteristic frequency of a main filter whose characteristic frequency is adjustable with a reference signal frequency served as a target frequency, the filter automatic adjustment circuit comprising:
a reference filter having a plurality of modes that can be selectively changed over, the reference filter filtering an inputted reference signal and outputting a filtered signal;
a phase difference detector for detecting a phase difference between an input signal inputted to the reference filter and an output signal from the reference filter, and outputting a signal having a duty ratio corresponding to a phase difference caused by the reference filter;
a counter for counting a duty ratio corresponding to the phase difference caused by the reference filter based on input signals including the output signal from the phase difference detector and the reference signal, and outputting a signal representing a counted duty ratio;
a decoder for decoding the output signal from the counter into a control signal for variation correction on the main filter made based on the reference filter;
a plurality of registers for each holding and outputting the control signal outputted from the decoder; and
a plurality of main filters for each performing filtering signal processing so as to select the characteristic frequency in accordance with the respective control signals outputted from the plurality of registers,
wherein each of the main filters and the reference filter is an active filter using an operational amplifier, and
wherein the reference filter is able to perform mode change.

2. The filter automatic adjustment circuit as claimed in claim 1,
wherein the reference filter performs the mode change by one of the following:
(a) selective changeover between a MOS (Metal-Oxide-Semiconductor) capacitor and a MOM (Metal-Oxide-Metal) capacitor; and
(b) selective changeover between a MOS capacitor and a MIM (Metal-Insulator-Metal) capacitor.

3. The filter automatic adjustment circuit as claimed in claim 1,
wherein the reference filter performs the mode change by selective changeover between a PS (polysilicon) resistor and a diffused resistor.

4. The filter automatic adjustment circuit as claimed in claim 1,
wherein the reference filter has a phase difference of 90 degrees or −90 degrees to be generated when a signal of the characteristic frequency is given.

5. The filter automatic adjustment circuit as claimed in claim 1,
wherein the reference filter performs the mode change by selective changeover among a plurality of devices of same type having different shapes.

6. The filter automatic adjustment circuit as claimed in claim 1,
wherein the reference filter is able to change the characteristic frequency.

7. The filter automatic adjustment circuit as claimed in claim 1,
wherein the reference phase difference detector is an AND circuit.

8. The filter automatic adjustment circuit as claimed in claim 1, further comprising a judgment part for performing one of performing readjustment, issuing an output signal of an error indication, and issuing an instruction to use a preceding result, when the adjustment results of the plurality of filters do not conform to a selection condition based on one of the output signal from the counter, the output signal from the decoder, and the output signal from the register.

9. The filter automatic adjustment circuit as claimed in claim 1,
wherein the main filter is used in place of the reference filter by performing changeover instead of providing the reference filter.

10. A filter automatic adjustment method for adjusting a characteristic frequency of a main filter whose characteristic frequency is adjustable with a reference signal frequency served as a target frequency, the method including the steps of:
setting a reference filter into a first mode, the reference filter having a plurality of modes that can be selectively changed over, and filtering an inputted reference signal and outputting a filtered signal;
inputting the reference signal to the reference filter;
counting a duty ratio between an input signal inputted to the reference filter and an output signal from the reference filter in the first mode, and outputting a count number;
decoding the count number into a decoded value in the first mode;
storing the decoded value into a first register in the first mode;
setting the reference filter into a second mode;
counting a duty ratio between the input signal inputted to the reference filter and the output signal from the reference filter in the second mode, and outputting a count number;
decoding the count number in the second mode into a decoded value; and
storing the decoded value into a second register in the second mode.

11. The filter automatic adjustment method as claimed in claim 10, further including a step of changing the frequency of the reference signal inputted to the reference filter when a changeover from the first mode to the second mode is performed.

12. The filter automatic adjustment method as claimed in claim 11, further including a step of counting the duty ratio between the input signal inputted to the reference filter and the output signal from the reference filter in the second mode, outputting a count number, then judging adjustment results based on one of the count numbers, the decoded values, and the output signals from the first and second register in the first mode and the second mode, and performing one of readjustment, issuing an output signal of an error indication and using a preceding result when the adjustment results do not conform to a selection condition.

13. The filter automatic adjustment method as claimed in claim 11, further including a step of writing one of the count numbers, the decoded values, and the output signals from the first and second registers into a nonvolatile memory in a manufacturing process of a wireless communication apparatus.

14. A wireless communication apparatus comprising:
a main filter for filtering a signal inputted from an antenna, the main filter having been undergone filter adjustment by a filter automatic adjustment circuit to remove interference waves of frequencies different from a target frequency; and
a baseband signal processing part for inputting the signal from which the interference waves have been removed from the main filter, and converting the signal into audio and data,
wherein the filter automatic adjustment circuit is provided for adjusting a characteristic frequency of a main filter whose characteristic frequency is adjustable with a reference signal frequency served as a target frequency,
wherein the filter automatic adjustment circuit comprises:
a reference filter having a plurality of modes that can be selectively changed over, the reference filter filtering an inputted reference signal and outputting a filtered signal;
a phase difference detector for detecting a phase difference between an input signal inputted to the reference filter and an output signal from the reference filter, and outputting a signal having a duty ratio corresponding to a phase difference caused by the reference filter;
a counter for counting a duty ratio corresponding to the phase difference caused by the reference filter based on input signals including the output signal from the phase difference detector and the reference signal, and outputting a signal representing a counted duty ratio;
a decoder for decoding the output signal from the counter into a control signal for variation correction on the main filter made based on the reference filter;
a plurality of registers for each holding and outputting the control signal outputted from the decoder; and
a plurality of main filters for each performing filtering signal processing so as to select the characteristic frequency in accordance with the respective control signals outputted from the plurality of registers,
wherein each of the main filters and the reference filter is an active filter using an operational amplifier, and
wherein the reference filter is able to perform mode change.

15. The wireless communication apparatus as claimed in claim 14,
wherein the wireless communication apparatus is a portable telephone system.
